(19) United States
(12) Patent Application Publication
(10) Pub. No.: US 2011/0241657 A1
(43) Pub. Date: Oct. 6, 2011

(54) INPUT DEVICE

(75) Inventors: HIROAKI NISHIONO, Osaka (JP); ERIKA SAWADA, Osaka (JP); TAMOTSU YAMAMOTO, Hyogo (JP)

(73) Assignee: PANASONIC CORPORATION, Osaka (JP)

(21) Appl. No.: 13/045,729

(22) Filed: Mar. 11, 2011

(30) Foreign Application Priority Data
Mar. 30, 2010 (JP) 2010-078350

(51) Int. Cl. G01R 33/02

(52) U.S. Cl. 324/207.13

(57) ABSTRACT

An input device including multiple magnets rotatably disposed, multiple magnetic field detecting elements, and a controller. The magnets have the N pole and the S pole formed at a predetermined angular pitch in a rotating direction. The magnetic field detecting elements are disposed facing the magnets. The controller outputs a driving signal in response to a pulse signal output from the magnetic field detecting elements. The controller changes the driving signal to be output in response to a time difference or the number of pulses of pulse signals output from the magnetic field detecting elements.

### BACKGROUND OF THE INVENTION

1. Field of the Invention

The present invention relates to input devices used for operating a range of electronic apparatus.

2. Background Art

Functions and downsizing are further advancing in a range of electronic apparatus, such as mobile phones and personal computers. In response to these advancements, input devices that allow simple but wide-ranging operations are also in demand for operating these electronic apparatus.

A conventional input device is described next. FIG. 9 is a perspective view of a structure of the conventional input device. FIG. 10 is a sectional view of the structure of the conventional input device.

As shown in FIGS. 9 and 10, conventional input device 10 includes upper case 1, lower case 2, magnets 3A to 3D, wiring board 5, four magnetic field detecting elements 6, controller 7, and cover sheet 8.

Upper case 1 and lower case 2 are made of insulating resin, respectively. Magnets 3A to 3D have a substantially spherical shape. On magnets 3A to 3D, the N pole and the S pole that have different magnetism are formed adjacently at a predetermined angular pitch in a rotating direction.

Magnet 3A and magnet 3B that faces this magnet 3A are rotatably mounted on lower case 2 in a horizontal direction (the x direction in FIG. 9), and magnet 3C and magnet 3D are rotatably mounted on lower case 2 in a front-back direction (the y direction in FIG. 9) perpendicular to the direction of magnet 3A and magnet 3B. Upper parts of magnets 3A to 3D are protruding from the top face of upper case 1, respectively. Wiring board 5 has multiple wiring patterns (not illustrated) on its top and bottom faces. On the top face of wiring board 5, four magnetic field detecting elements 6, such as a hall element, for detecting a perpendicular magnetic field are mounted at positions facing magnets 3A to 3D, respectively.

Controller 7, such as a microcomputer, is connected to multiple magnetic field detecting elements 6. Cover sheet 8 is a film, and it covers the top face of wiring board 5 where magnetic field detecting elements 6 and controller 7 are mounted.

Input device 10 as configured above is placed in an operating part (not illustrated) of an electronic apparatus, such as a mobile phone and personal computer, with the upper parts of magnets 3A to 3D protruding upward. Controller 7 is electrically coupled to an electronic circuit (not illustrated) of the electronic apparatus via a wiring pattern and lead wire (not illustrated).

The operation of input device 10 as configured above is described below. FIGS. 11A and 11B are plan views for illustrating the operation of conventional input device 10. FIGS. 12A and 12B are waveform charts for illustrating the operation of conventional input device 10. Here, let's assume that multiple menus, such as names and song titles, and a cursor (not illustrated) are displayed on a display unit (not illustrated), such as a liquid crystal display device, of the electronic apparatus. In this state, as shown in FIG. 11A, let's say the user moves the finger rightward. In this case, magnet 3C and magnet 3D that are rotatable in the front-back direction perpendicular to the finger movement direction do not rotate. However, magnet 3A that is rotatable in the horizontal direction first rotates, and then magnet 3B rotates.

The N pole and the S pole of magnet 3A are formed adjacently at a predetermined angular pitch in the rotating direction. Accordingly, magnetic field detecting element 6 disposed below magnet 3A detects a magnetic field that the N pole and the S pole alternately changes by the rotation of magnet 3A. Magnetic field detecting element 6 disposed below magnet 3A outputs pulse signal L1 shown in FIG. 12A. Magnetic field detecting element 6 disposed below magnet 3B also outputs pulse signal L2 shown in FIG. 12A. By the aforementioned operation, magnet 3A first rotates, and then magnet 3B rotates. Pulse signal L1 and pulse signal L2 are thus signals with a phase difference of a predetermined time, such as a difference of time t. These signals are output to controller 7.

Controller 7 detects the finger movement direction and rotating angles of magnet 3A and magnet 3B based on pulse signal L1 and pulse signal L2. Controller 7 then outputs driving signal M1 shown in FIG. 12B to the electronic circuit of the electronic apparatus for a period from rising of pulse signal L1 to falling of pulse signal L2. This makes the cursor, for example, on a menu displayed on the display unit of the electronic apparatus move in a predetermined direction, such as to the right, in response to the rotating angles of magnet 3A and magnet 3B.

If the finger is moved leftward, magnet 3B first rotates, contrary to the above example, and then magnet 3A rotates. In addition, if the finger is moved in the front-back direction, as shown in FIG. 11B, magnet 3A and magnet 3B do not rotate. Instead, magnet 3C and magnet 3D that are rotatable in the front-back direction rotate. Magnetic field detecting elements 6 disposed below magnet 3C and magnet 3D output pulse signal L1 and pulse signal L2 with a phase difference, same as the case shown in FIG. 12A, to controller 7. The cursor on the display unit of the electronic apparatus moves in a predetermined direction, such as to the left or in the vertical direction, by these operations.

In other words, conventional input device 10 enable the cursor, for example, shown on the display unit to move in a predetermined direction for selecting a menu by rotating magnets 3A to 3D in the horizontal direction or front-back direction while the user looks at the display unit of the electronic apparatus.

A known prior art related to the present invention is a patent literature of Japanese Patent Unexamined Publication No. 2009-104371.

In aforementioned conventional input device 10, the user rotates magnets 3A to 3D by moving the finger in the horizontal direction or front-back direction. With this movement, controller 7 outputs driving signal M1 corresponding to rotating angles of magnets 3A to 3D, so as to move the cursor.

However, if many menus are displayed, for example, the user needs to move the finger in a predetermined direction several times to rotate magnets 3A to 3D in order to move the cursor on the display unit for a long distance in the predetermined direction. This is cumbersome and troublesome operation.

### SUMMARY OF THE INVENTION

The present invention solves a conventional disadvantage, and offers an input device that allows simple but wide-ranging operations.

The present invention is an input device including multiple magnets, multiple magnetic field detecting elements, and a controller. The magnets are rotatably disposed with the N pole and the S pole formed at a predetermined angular pitch in a rotating direction. The magnetic field detecting elements are disposed facing the magnets. The controller outputs a driving signal corresponding to pulse signals output from the magnetic field detecting elements. The controller changes the driving signal that is output based on a time difference of pulse signals or the number of pulses output from the magnetic field detecting elements.

### BRIEF DESCRIPTION OF THE DRAWINGS

FIG. 1 is a perspective view of an input device in accordance with a first exemplary embodiment of the present invention.

FIG. 2 is a sectional view of the input device in accordance with the first exemplary embodiment of the present invention.

FIG. 3 is an exploded perspective view of the input device in accordance with the first exemplary embodiment of the present invention.

FIG. 4 is a fragmentary side view of a part illustrating a relation of a magnet and magnetic field detecting element disposed below.

FIG. 5A a plan view illustrating the operation of the input device in accordance with the first exemplary embodiment of the present invention.

FIG. 5B is a plan view illustrating the operation of the input device in accordance with the first exemplary embodiment of the present invention.

FIG. 6A is a waveform chart for illustrating a signal output from the magnetic field detecting element of the input device in accordance with the first exemplary embodiment of the present invention.

FIG. 6B is a waveform chart for illustrating a signal output from the magnetic field detecting element of the input device in accordance with the first exemplary embodiment of the present invention.

FIG. 6C is a waveform chart for illustrating a signal output from the magnetic field detecting element of the input device in accordance with the first exemplary embodiment of the present invention.

FIG. 7A is a waveform chart for illustrating a signal output from a magnetic field detecting element of an input device in accordance with a second exemplary embodiment of the present invention.

FIG. 7B is a waveform chart for illustrating a signal output from the magnetic field detecting element of the input device in accordance with the second exemplary embodiment of the present invention.

FIG. 7C is a waveform chart for illustrating a signal output from the magnetic field detecting element of the input device in accordance with the second exemplary embodiment of the present invention.

FIG. 8A is a plan view of another structure of an input device in accordance with an exemplary embodiment of the present invention.

FIG. 8B is a plan view of another structure of an input device in accordance with an exemplary embodiment of the present invention.

FIG. 8C is a plan view of another structure of an input device in accordance with an exemplary embodiment of the present invention.

FIG. 9 is a perspective view of a structure of a conventional input device.

FIG. 10 is a sectional view of the structure of the conventional input device.

FIG. 11A is a plan view illustrating the operation of the conventional input device.

FIG. 11B is a plan view illustrating the operation of the conventional input device.

FIG. 12A is a waveform chart for illustrating the operation of the conventional input device.

FIG. 12B is a waveform chart for illustrating the operation of the conventional input device.

### DETAILED DESCRIPTION OF THE INVENTION

Exemplary embodiments of the present invention are described below with reference to drawings.

### First Exemplary Embodiment

Input device 20 in the first exemplary embodiment of the present invention is described below.

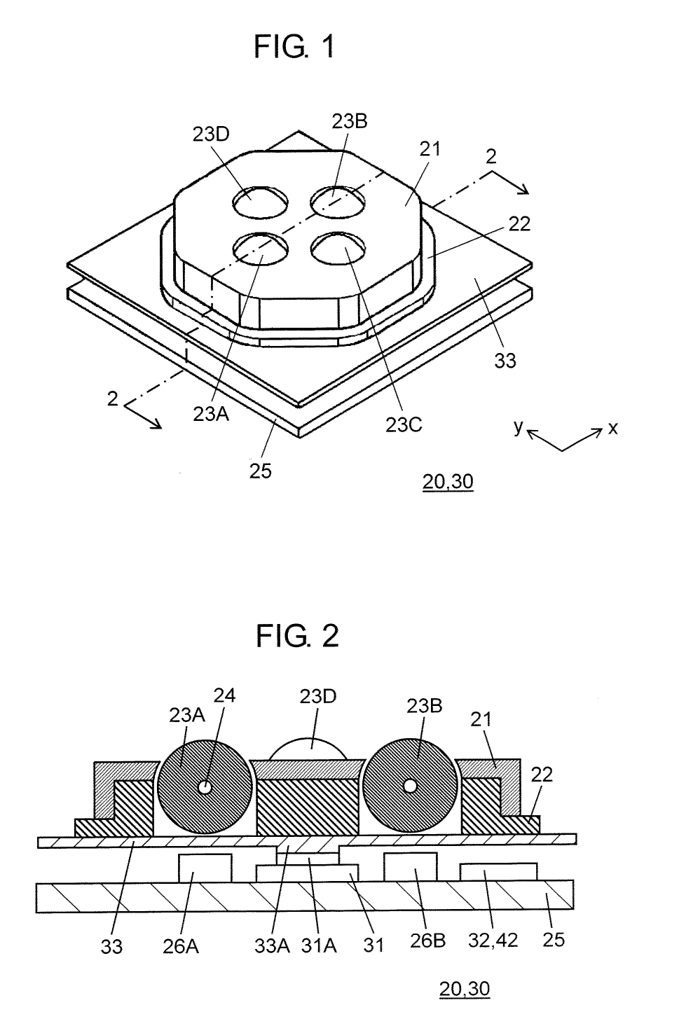

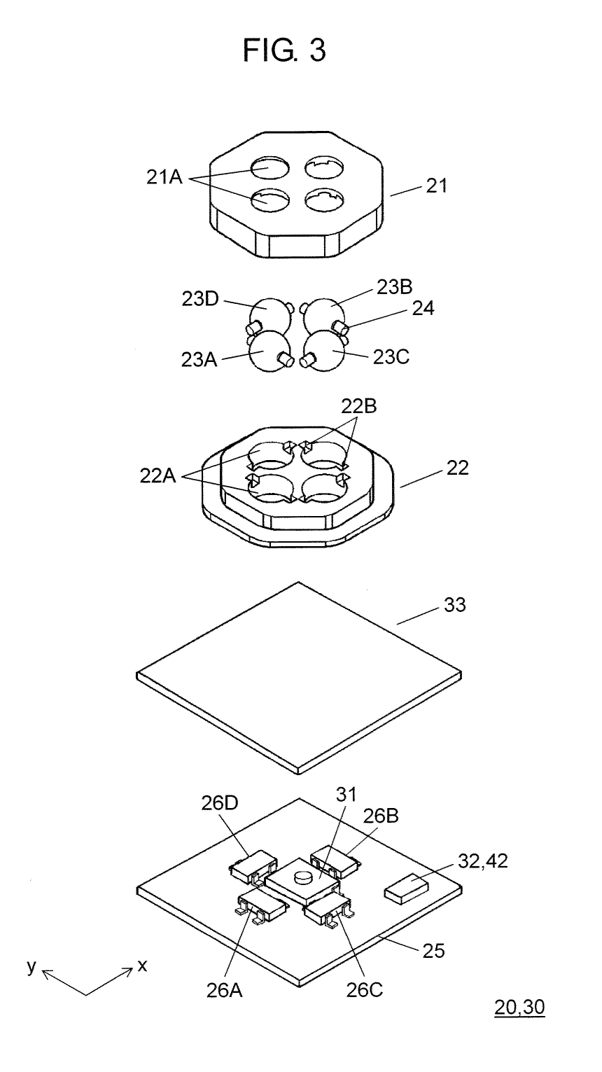

FIG. 1 is a perspective view of input device 20 in the first exemplary embodiment of the present invention. FIG. 2 is a sectional view of input device 20, and FIG. 3 is an exploded perspective view of input device 20.

As shown in FIGS. 1, 2, and 3, input device 20 includes upper case 21, lower case 22, magnets 23A to 23D, wiring board 25, four magnetic field detecting elements 26A to 26D, switch contact 31, controller 32, and cover sheet 33.

Upper case 21 is made of insulating resin such as ABS. Lower case 22 is made of insulating resin such as polyacetal. Multiple round openings 22A, such as four openings 22A in this exemplary embodiment, and a pair of semi-cylindrical holders 22B attached to each of openings 22A are formed on lower case 22. Upper case 21 has four round openings 21A slightly smaller than openings 22A.

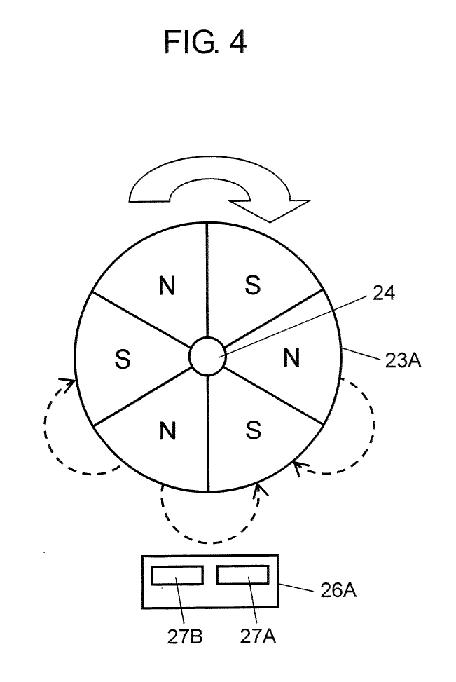

Magnets 23A to 23D have a substantially spherical shape with diameter of 2 to 3 mm, and typically contain ferrite or alloy of Nd—Fe—B. A structure of magnets 23A to 23D is described with reference to magnet 23A as an example. FIG. 4 is a fragmentary side view illustrating the relation of magnet 23A and magnetic field detecting element 26A disposed below in the first exemplary embodiment of the present invention.

In magnet 23A, as shown in FIG. 4, the N pole and the S pole that have different magnetism are formed adjacently at a predetermined angle pitch in a rotating direction. For example, the N pole and the S pole are provided at a 60-degree pitch in this exemplary embodiment. A pair of protruding cylindrical rotating shafts 24 is provided at the rotating center of magnet 23A. Magnets 23B to 23D have the same structure as magnet 23A.

These multiple magnets, typically four magnets 23A to 23D in this exemplary embodiment, are placed in openings 22A with their rotating shafts 24 inserted into holders 22B in lower case 22.

In this exemplary embodiment, as shown in FIGS. 2 and 3, magnet 23A (first magnet) and magnet 23B (second magnet) facing this magnet 23A are rotatably placed in the horizontal direction (the x-axis direction in FIG. 3, first direction), and magnet 23C (third magnet) and magnet 23D (fourth magnet) facing this magnet 23C are rotatably placed in the front-back direction (the y-axis direction in FIG. 3, second direction), which is perpendicular to the direction of magnet 23A and magnet 23B. As shown in FIGS. 1 and 2, upper parts of magnets 23A to 23D are protruding from openings 21A on the top face of upper case 21, respectively.

These four openings 21A, four openings 22A, and magnets 23A to 23D are provided at a distance of around 3 to 5 mm to achieve dimensions within the width of one finger, which is around 4 to 10 mm. This is to enable touching of these four magnets 23A to 23D simultaneously with one finger.

Wiring board 25 is typically configured with paper phenol or glass epoxy. Multiple wiring patterns (not illustrated) are formed on the top and bottom faces of wiring board 25, typically using copper foil.

On the top face of wiring board 25, four magnetic field detecting elements 26A to 26D, such as a hall element for detecting perpendicular magnetic field and a GMR element for detecting a horizontal magnetic field, are mounted facing magnets 23A to 23D, respectively.

As shown in FIG. 4, these magnetic field detecting elements 26A to 26D include magnetic field detecting element 27A for detecting a perpendicular magnetic field, and magnetic field detecting element 27B for detecting a horizontal magnetic field that is orthogonal to the perpendicular direction, respectively.

Switch contact 31 is typically configured with a push switch. Controller 32 includes a microcomputer. Switch contact 31 is mounted at the center of the top face of wiring board 25 where four magnetic field detecting elements 26A to 26D are disposed. Switch contact 31 and magnetic field detecting elements 26A to 26D are connected to controller 32 via a wiring pattern.

Cover sheet 33 is a film typically configured with polyethylenetelephthalate. Cover sheet 33 covers the top face of wiring board 25. Protrusion 33A is formed typically by printing on the bottom face of cover sheet 33. Protrusion 33A is making contact with push button 31A protruding upward from switch contact 31. With this structure, push button 31A of switch contact 31 is pressed down when cover sheet 33 is pressed.

Input device 20 as configured above is installed in an operating part (not illustrated) of an electronic apparatus, such as a mobile phone and a personal computer, such that input device 20 is vertically movable with the upper parts of magnets 23A to 23D protruding from the operating part. Controller 32 is electrically coupled to an electronic circuit (not illustrated) of the electronic apparatus typically via wiring pattern and lead wire (not illustrated).

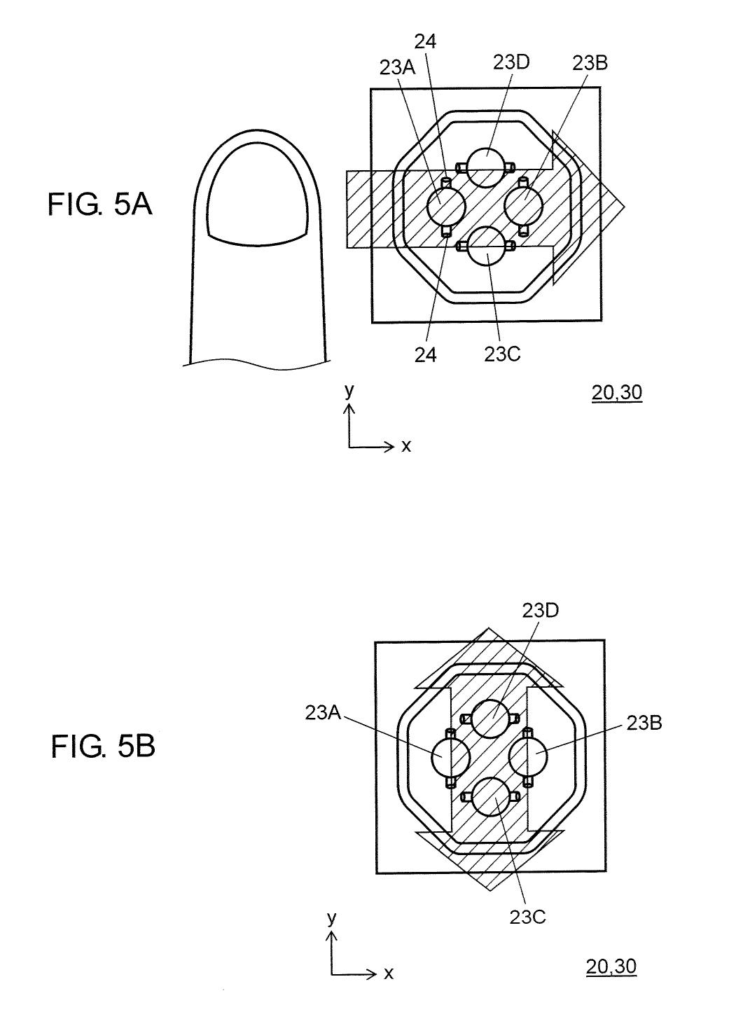

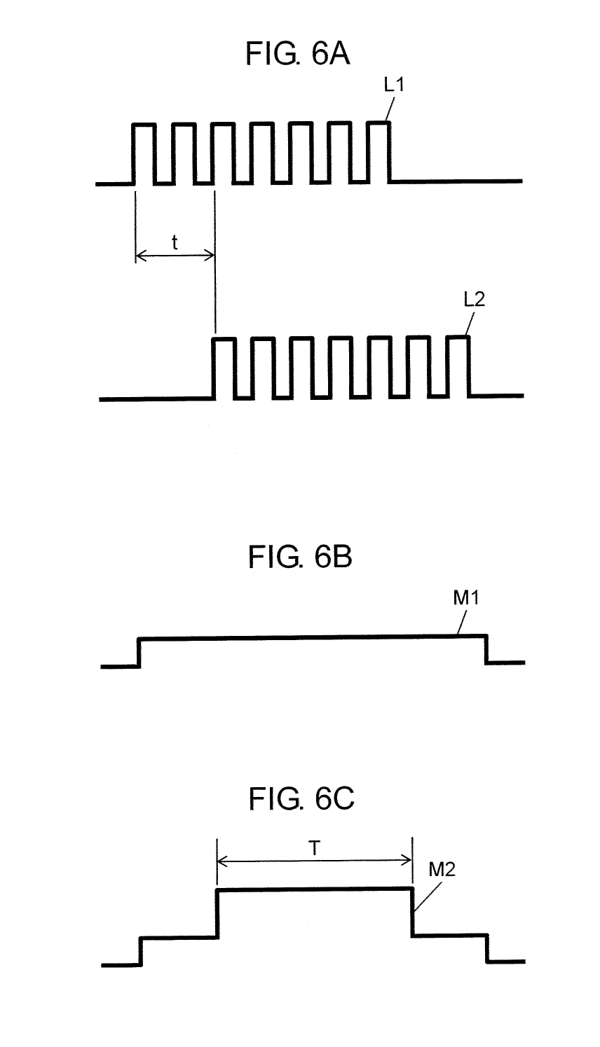

The operation of input device 20 is described next. FIGS. 5A and 5B are plan views for illustrating the operation of input device 20 in the first exemplary embodiment of the present invention. FIGS. 6A, 6B, and 6C are waveform charts for illustrating signals output from magnetic field detecting elements 26A to 26D of input device 20 in the first exemplary embodiment of the present invention. For example, let's assume that multiple menus, such as names and music titles, and a cursor (not illustrated) are displayed on a display unit (not illustrated), such as a liquid crystal display device, of the electronic apparatus. In this state, as shown in FIG. 5A, if the finger is moved rightward (in the x-axis direction), magnet 23C and magnet 23D that are rotatable in the front-back direction (the y-axis direction) perpendicular to the x-axis direction do not rotate. However, magnet 23A that is rotatable in the horizontal direction (the x-axis direction) rotates about rotating shaft 24, and then magnet 23B rotates.

As shown in FIG. 4, the N pole and S pole are adjacently formed at a predetermined angular pitch in magnet 23A. Accordingly, magnetic field detecting element 26A (first magnetic field detecting element) below magnet 23A detects a magnetic field of magnet 23A that alternately changes between the N pole and S pole. At this point, magnetic field detecting element 27A for detecting the perpendicular magnetic field detects the number of changes between the N pole and S pole of magnet 23A, i.e., a rotating angle.

Magnetic field detecting element 27B for detecting the horizontal magnetic field detects the magnetic field of magnet 23A such that whether a change is from the N pole to S pole or from the S pole to N pole, i.e., the rotating direction of magnet 23A.

Then, magnetic field detecting element 26A outputs pulse signal L1 shown in the waveform chart of FIG. 6A to controller 32.

Magnetic field detecting element 26B (second magnetic field detecting element) disposed below magnet 23B also outputs pulse signal L2 shown in FIG. 6A. However, in the case of operation in FIG. 5A, magnet 23A rotates first, and then magnet 23B rotates. Therefore, pulse signal L1 and pulse signal L2 are signals with a phase difference of a predetermined time, for example, time t. These signals are output from magnetic field detecting elements 26A and 26B to controller 32.

Based on pulse signal L1 and pulse signal L2 received, controller 32 detects the movement direction of finger and the rotating angle of magnet 23A and magnet 23B. Controller 32 then outputs driving signal M1 (first driving signal) to the electronic circuit of the electronic apparatus during a period from rising of pulse signal L1 to falling of pulse signal L2. This makes the cursor, for example, on the menus displayed on the display unit of the electronic apparatus move rightward, for example, based on the rotating angles of magnet 23A and magnet 23B.

If the finger is moved quickly, a time difference reduces between pulse signal L1 output from magnetic field detecting element 26A below magnet 23A and pulse signal L2 output from magnetic field detecting element 26B below magnet 23B. Controller 32 distinguishes this time difference t (hereafter referred to as “phase-difference time”) when it becomes a predetermined value or below, and outputs driving signal M2 (second driving signal), as shown in FIG. 6C, to the electronic circuit of the electronic apparatus. Driving signal M2 has a waveform that is different from driving signal M1 in period T while both magnet 23A and magnet 23B are rotated. This is the driving signal for quickly moving the cursor on the display unit of the electronic apparatus.

Driving signal M2 in FIG. 6C is detailed next. When the user first rotates magnet 23A, controller 32 outputs a signal with a waveform same as driving signal M1. Then, the finger makes contact with both magnet 23A and magnet 23B, and controller 32 outputs driving signal M2 while both magnet 23A and magnet 23B rotate (period T). When the electronic circuit of the electronic apparatus receives driving signal M2, the cursor moves rightward at a speed different from the normal speed, for example, twice or three times faster than the normal speed. If the finger is further moved rightward and released from magnet 23A, leaving only magnet 23B rotated, a waveform same as driving signal M1 is output again, and the cursor moves rightward at the normal speed on the display unit of the electronic apparatus.

In other words, in input device 20 in the preferred embodiment, controller 32 outputs driving signal M1 if the user moves the finger rightward at the normal speed. On the other hand, if the user quickly moves the finger, and thus phase-difference time t becomes a predetermined value or below, controller 32 outputs driving signal M2. In this case, the cursor moves rightward on the display unit of the electronic apparatus at a speed different from the normal speed, for example, twice or three times faster than the normal speed.

As described above, to move the cursor rightward for a long distance if many menus are displayed, this input device 20 eliminates the need of rotating magnet 23A and magnet 23B several times by moving the finger back and forth several times in the horizontal direction. In this case, the user just needs to quickly move the finger once to quickly rotate magnets 23A and 23B so as to move the cursor for a long distance.

If the user moves the finger leftward on input device 20, magnet 23B rotates leftward, and then magnet 23A rotates leftward, which is opposite to the above description. As shown in FIG. 5B, if the finger is moved in the front-back direction (the y-axis direction in FIG. 5B), magnet 23A and magnet 23B do not rotate, and magnet 23C and magnet 23D that are rotatable in the front-back direction rotate. Then, magnetic field detecting elements 26C (third magnetic field detecting element) and 26D (fourth magnetic field detecting element) disposed below magnet 23C and magnet 23D output pulse signal L1 and pulse signal L2 that have a phase difference to controller 32, same as the above description. This enables the cursor on the display unit of the electronic apparatus to move, for example, leftward or vertically.

In the same way, if phase-difference time t of pulse signals output from two opposing magnetic field detecting elements (magnetic field detecting elements 26B and 26A in the case of moving leftward, and magnetic field detecting elements 26C and 26D in the case of moving in the front-back direction) is a predetermined value or below by quickly moving the finger leftward or in the front-back direction on input device 20, controller 32 outputs driving signal M2. This enables to quickly move the cursor leftward or in the front-back direction on menus for a long distance.

In other words, the cursor displayed on the display unit is moved in a predetermined direction to select a menu by rotating magnets 23A to 23D in the horizontal direction or front-back direction by the finger while the user looks at the display unit of the electronic apparatus. If the user quickly moves the finger in a predetermined direction, and phase-difference time t of pulse signals output from magnetic field detecting elements 26A to 26D become a predetermined value or below, the cursor can be quickly moved to select a menu swiftly in a short time.

When the user places the cursor on a desired menu, and magnets 23A to 23D are pressed by the finger, upper case 21 and lower case 22 moves downward to dent cover sheet 33. Protrusion 33A formed on the bottom face of cover sheet 33 presses push button 31A, and switch contact 31 makes electrical connection or disconnection. Controller 32 detects this electrical connection or disconnection of switch contact 31, and a predetermined operation such as menu determination or display of next menu, can be executed on the side of electronic apparatus.

If the user releases the pressing force applied to magnets 23A to 23D, push button 31A pushes up protrusion 33A by the resilient recovery force of switch contact 31, and then upper case and lower case 22 moves upward to recover to the original state.

In this way, by using input device 20 in the exemplary embodiment, the user can move the cursor in response to the movement speed of finger so as to select a menu while looking at the display unit of the electronic apparatus, and can also easily determine a menu or display the next menu by pressing operation of magnets 23A to 23D.

As described above, the exemplary embodiment changes a driving signal output from controller 32 in response to a time difference of pulse signals output from magnetic field detecting elements 26A to 26D. More specifically, if the finger moves at the normal speed, and phase-difference time t is greater than a predetermined value, controller 32 outputs driving signal M1. If the finger is quickly moved and phase-difference time t is not greater than the predetermined value, controller 32 outputs driving signal M2. This allows diversifying movements of cursor on the side of electronic apparatus in response to each finger movement speed. Accordingly, the present invention offers an input device that allows simple but wide-ranging operations, typically using a cursor.

### Second Exemplary Embodiment

Next, the second exemplary embodiment of the present invention is described.

Input device 30 in this exemplary embodiment has a structure same as that of input device 20 described in the first exemplary embodiment, and thus its description is omitted.

In comparison with input device 20 in the first exemplary embodiment, input device 30 has controller 42 whose operation is different from controller 32.

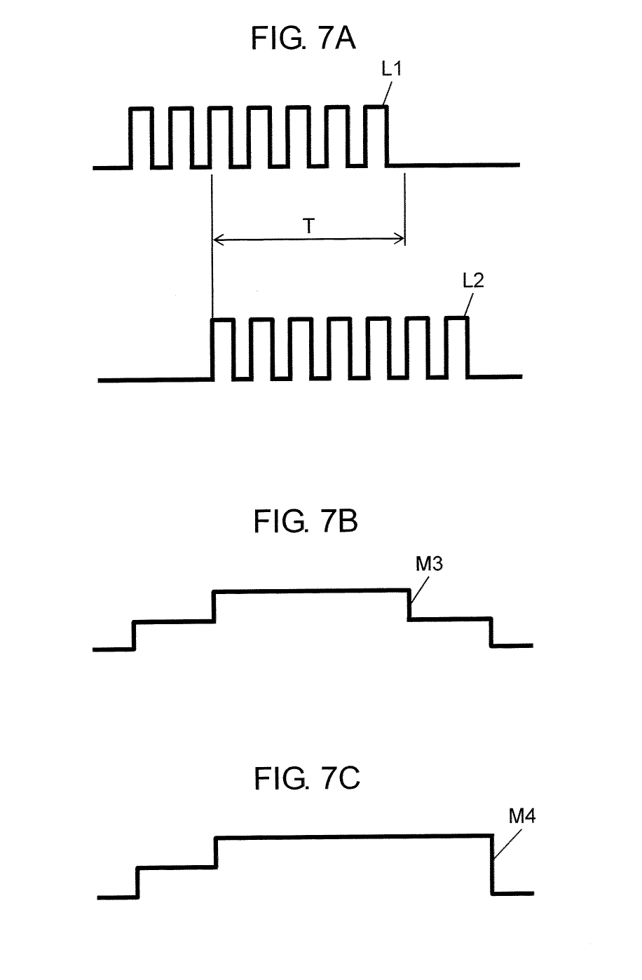

The operation of input device 30 is described next. FIGS. 7A, 7B, and 7C are waveform charts for illustrating signals output from magnetic field detecting elements 26A to 26D of input device 30 in the second exemplary embodiment of the present invention.

In the structure shown in FIGS. 1 to 4, let's assume that multiple menus, such as names or song titles, and a cursor (not illustrated) are displayed on a display unit (not illustrated), such as a liquid crystal display device, of an electronic apparatus. In this state, as shown in FIG. 5A, magnet 23A first rotates and then magnet 23B rotates by moving the finger rightward.

Same as the first exemplary embodiment, magnetic field detecting element 26A disposed below detects a change of magnetic field of this magnet 23A, and outputs the rotating direction of magnet 23A and pulse signal L1 corresponding to the rotating angle, as shown by the waveform chart in FIG. 7A, to controller 42.

Magnetic field detecting element 26B disposed below magnet 23B outputs pulse signal L2 that has a phase difference shifted for a predetermined time from pulse signal L1, as shown in FIG. 7A.

Controller 42 detects the finger movement direction and the rotating angle of magnet 23A and magnet 23B based on these pulse signals L1 and L2. Here, controller 42 counts the number of pulses in pulse signal L1 and pulse signal L2, and outputs driving signal M3 (third driving signal), as show in FIG. 7B, to the electronic circuit of the electronic apparatus. Driving signal M3 is a driving signal that has a waveform amplitude larger than that of driving signal M1 during period T, i.e., a period with large number of pulses, when both magnet 23A and magnet 23B are rotated. This driving signal M3 is a signal for quickly moving the cursor, for example, on the electronic circuit of the electronic apparatus.

More specifically, when magnet 23A is first rotated, as shown in FIG. 7B, controller 42 outputs a signal with a waveform same as normal driving signal M1. Then, when the finger makes contact with both magnet 23A and magnet 23B, and both magnet 23A and magnet 23B are rotated (period T), controller 42 outputs driving signal M3. As a result, the cursor moves rightward, for example, at twice the normal speed in the electronic apparatus. If the user further moves the finger and the finger is released from magnet 23A, leaving only magnet 23B rotated, a signal with a waveform same as driving signal M1 is output to move the cursor rightward at the normal speed.

In other words, in input device 30 in this exemplary embodiment, the cursor, for example, can be moved rightward at twice the normal speed while the number of pulses counted by controller 42 is increased by rotating both magnets 23A and 23B. Accordingly, there is no need to rotate magnet 23A and magnet 23B several times by moving the finger in the horizontal direction back and forth. The cursor can be moved for a long distance just by moving the finger once.

If the finger is quickly moved and the number of pulses counted exceeds a predetermined number while both magnet 23A and magnet 23B are rotated, controller 42 outputs driving signal M4 (fourth driving signal) for quickly moving the cursor, for example, twice the normal speed also when only magnet 23B is rotated, as shown in FIG. 7C.

Accordingly, input device 30 in this exemplary embodiment moves the cursor at a speed different from the normal speed, for example twice the normal speed, while both magnet 23A and magnet 23B are rotated even if the finger is moved rightward once at the normal speed. In addition, if the user quickly moves the finger, the cursor can be moved at twice the normal speed even if only magnet 23B is rotated.

Still more, if the user moves the cursor leftward, a direction opposite to that in the above description, or in the front-back direction, as shown in FIG. 5B, the cursor also moves at, for example, twice the normal speed while both of two opposing magnets are rotated. If the finger is quickly moved, the cursor can be quickly moved at, for example, twice the normal speed, leftward or in the front-back direction on the menus for a long distance also while only the magnet operated afterward continues its rotation.

Still more, also in input device 30 in this exemplary embodiment, electrical connection or disconnection of switch contact 31 is feasible by applying the user's finger to magnets 23A to 23D and pressing them in a state that the cursor is placed on a desired menu on the display unit of the electronic apparatus. Controller 42 detects this movement, and executes a predetermined operation, such as menu determination or display of next menus. This is the same as the first exemplary embodiment.

As described above, controller 42 counts the number of pulses of pulse signals from magnetic field detecting elements 26A to 26D in this exemplary embodiment. In response to the number of pulses counted, a driving signal to be output changes. More specifically, for example, while both of two opposing magnets are rotated, driving signal M3 is output. Diversifying cursor movements are feasible in response to the speed of finger movement by outputting driving signal M4 if the user quickly moves the finger. This offers an input device that allows simple but wired-ranging operations, typically using a cursor.

The above description refers to an example of moving the cursor on the display unit of the electronic apparatus in the horizontal direction or vertical direction by moving magnets 23A to 23D in the left-right direction or the front-back direction with the user's finger. However, a direction input by input device 20 of the present invention is not limited to these directions. For example, the cursor can be moved in an oblique direction by moving the finger in an oblique direction. In this case, controllers 32 and 42 calculate a driving signal in the horizontal direction of the cursor based on outputs from magnetic field detecting elements 26A and 26B, and calculates a driving signal in the vertical direction of the cursor based on output from magnetic field detecting elements 26C and 26D. Then by synthesizing these movement vectors by controllers 32 and 42, the cursor can be moved at diversifying angles.

Still more, the above description refers to the structure of disposing magnetic field detecting elements 26A to 26D, which include a pair of magnetic field detecting element 27A for detecting perpendicular magnetic field and magnetic field detecting element 27B for detecting horizontal magnetic field, below magnets 23A to 23D, respectively. However, the input device of the present invention is not limited to this structure. For example, a magnetic field detecting element includes magnetic field detecting elements, which detect a magnetic field in the same direction, disposed in parallel at a predetermined interval. In this structure, controllers 32 and 42 detect rotating directions and rotating angles of magnets 23A to 23D based on a time difference caused by positional difference of these magnetic elements.

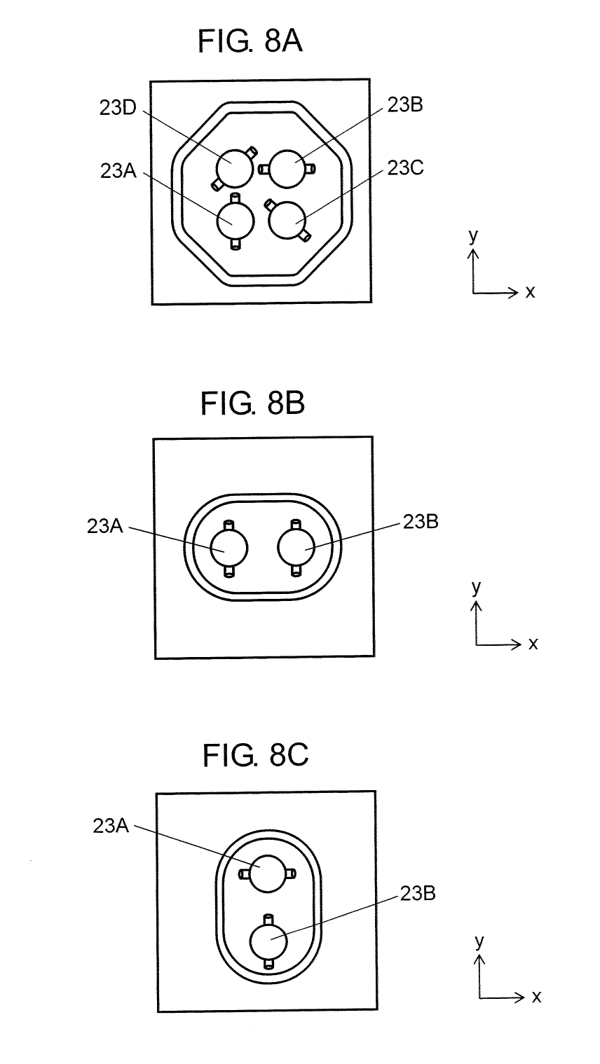

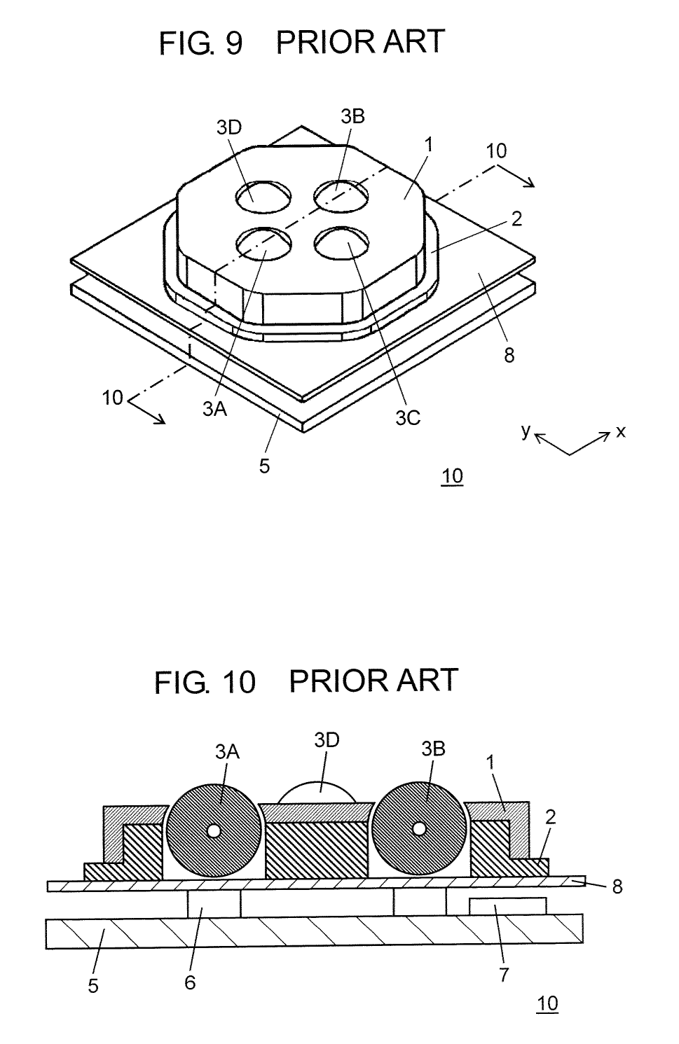

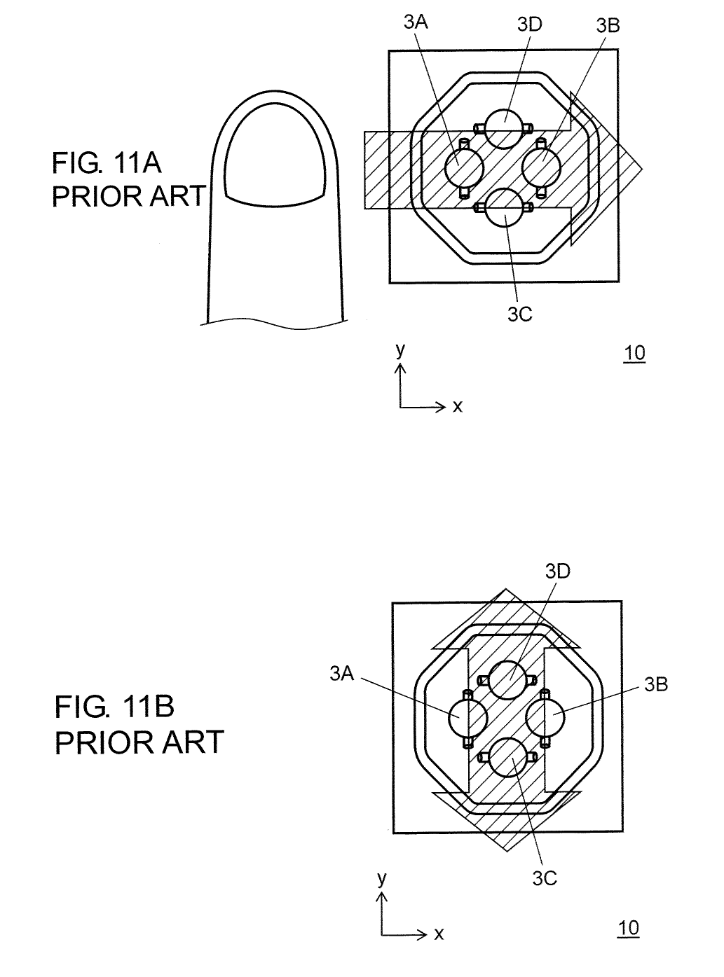

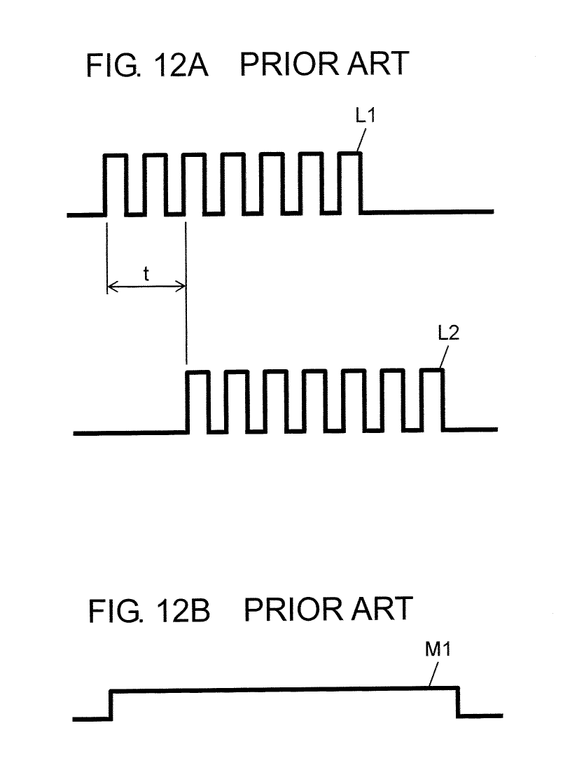

Still more, the above description refers to a structure of rotatably disposing magnet 23A and magnet 23B in the horizontal direction, and rotatably disposing magnet 23C and magnet 23D in the front-back direction in upper case 21 and lower case 22, respectively. However, the input device of the present invention is not limited to this structure. FIGS. 8A, 8B, and 8C are plan views of another structures of the input device in this exemplary embodiment of the present invention. For example, as shown in FIG. 8A, magnet 23A is rotatably placed in the horizontal direction, and magnet 23B is rotatably placed in the front-back direction. Magnet 23C and magnet 23D may be rotatably placed at a predetermined angle relative to these rotating axes, for example, in a direction tilted for 45 degrees.

Still more, if there is only a few operating directions, four magnets 23A to 23D may not be needed. As shown in FIG. 8B, two magnets 23A and 23B may be rotatably placed in the same direction in the structure.

In addition, as shown in FIG. 8C, magnet 23A and magnet 23B may be rotatably placed in directions perpendicular to each other. Furthermore, the number of magnets may be increased. For example, 8 magnets may be rotatably mounted in diversifying operating directions so as to detect diversifying directions.

In this case, controllers 32 and 42 change a driving signal to be output depending on a time difference or the number of pulses of pulse signals output from the opposing magnetic field detecting elements disposed opposing two magnets in magnets 23A to 23D in any of the structures shown in FIGS. 8A, 8B, and 8C.

Furthermore, the above description refers to an example of forming the N pole and the S pole at a predetermined angular pitch, for example, three poles each alternately at a 60-degree pitch, in the structure of magnets 23A and 23D shown in FIG. 4. However, the input device of the present invention is not limited to this structure. For example, a magnet in which one N pole and one S pole are formed at 180-degree pitch may be used. Or, a magnet in which four poles each are formed at a 45-degree pitch may be used. This may further increase the detection accuracy.

With respect to the shape of magnets 23A to 23D, diversifying shapes are applicable as long as the magnets are round to some extent and easy to rotate, such as a substantially cylindrical shape and substantially oval spherical shape, in addition to aforementioned nearly spherical shape.

In the exemplary embodiments, as described above, magnets 23A to 23D are placed in upper case 21 and lower case 22 with around 3 to 5 mm distance in between. This prevents output of pulse signals without phase difference due to simultaneous rotation of two magnets. In addition, this prevents output of one pulse signal due to rotation of only one of the magnets. Accordingly, rotating direction and rotating angle can be reliably detected.

In the above description, the push switch is mounted on the top face of wiring board 25 to configure switch contact 31. However, the present invention is not limited to this structure. A switch contact with diversifying structures is applicable. For example, multiple fixed contacts typically made of carbon are provided on a top face of wiring board 25, and a substantially dome-shaped movable contact made of thin conductive metal is placed on these fixed contacts. Or, a movable contact is formed on a bottom face of button typically made of rubber, and this button is placed over a fixed contact, facing the fixed contact.

Accordingly, the input device of the present invention has an advantageous effect of facilitating wide-ranging operations, and thus it is effectively applicable to input devices for operation in a range of electronic apparatus.

What is claimed is:

1. An input device comprising:
a plurality of magnets rotatably disposed, the magnets having a north pole and a south pole formed at a predetermined angular pitch in a rotating direction;
a plurality of magnetic field detecting elements disposed facing the plurality of magnets; and
a controller that outputs a driving signal in response to a pulse signal output from the plurality of magnetic field detecting elements;
wherein
the controller changes the driving signal to be output in response to one of a time difference and the number of pulses of the pulse signal output from the plurality of magnetic field detecting elements.

2. The input device of claim 1,
wherein
the plurality of magnets includes a first magnet and a second magnet that rotate in a first direction,
the plurality of magnetic field detecting elements include a first magnetic field detecting element disposed facing the first magnet, and a second magnetic field detecting element disposed facing the second magnet, and
the controller changes the driving signal to be output in response to one of a time difference and the number of pulses of a pulse signal output from the first magnetic field detecting element and the second magnetic field detecting element.

3. The input device of claim 2,
wherein
the plurality of magnets further includes a third magnet and a fourth magnet that rotate in a second direction perpendicular to the first direction,
the plurality of magnetic field detecting elements further include a third magnetic field detecting element disposed facing the third magnet, and a fourth magnetic field detecting element disposed facing the fourth magnet, and
the controller changes the driving signal to be output in response to one of a time difference and a pulse width of a pulse signal output from the third magnetic field detecting element and the fourth magnetic field detecting element.

4. The input device of claim 1, further comprising:
a wiring board where the plurality of magnetic field detecting elements and the controller are mounted; and
a cover sheet covering the wiring board, the cover sheet being formed under the plurality of magnets;
wherein
a switch contact with a push button is disposed on a top face of the wiring board and connected to the controller,
a protrusion is formed on a bottom face of the cover sheet and facing the push button, and
the push button of the switch contact is pressed down by pressing down the plurality of magnets.

5. The input device of claim 1,
wherein
each of the plurality of magnetic field detecting elements includes a magnetic field detecting element for detecting a perpendicular magnetic field, and a magnetic field detecting element for detecting a horizontal magnetic field.

6. The input device of claim 2,
wherein
the controller outputs a first driving signal with a predetermined waveform during a period from rising of a pulse signal output from the first magnetic field detecting element to falling of a pulse signal output from the second magnetic field detecting element.

7. The input device of claim 6,
wherein
the controller outputs a second driving signal with a waveform different from the first driving signal during a period that both the first magnet and the second magnet are rotated if a time difference between the pulse signal output from the first magnetic field detecting element and the pulse signal output from the second magnetic field detecting element is not greater than a predetermined value.

8. The input device of claim 6,
wherein
the controller outputs a third driving signal with a waveform different from the first driving signal during a period that both the first magnet and the second magnet are rotated.

9. The input device of claim 8,
wherein
the controller outputs a fourth driving signal with a waveform different from the first driving signal also while only the second magnet is rotated after both the first magnet and the second magnet are rotated if the number of pulses of the pulse signal output from the first magnetic field detecting element and the pulse signal output from the second magnetic field detecting element is not less than a predetermined number.
